(19) United States
(12) Patent Application Publication
(10) Pub. No.: US 2020/0058523 A1
(43) Pub. Date: Feb. 20, 2020

(54) GAS ETCHING DEVICE

(71) Applicant: INGENTEC CORPORATION, Miaoli County (TW)

(72) Inventors: YA-LI CHEN, MIAOLI COUNTY (TW); HSIANG-AN FENG, MIAOLI COUNTY (TW); CHENG-YU CHUNG, MIAOLI COUNTY (TW)

(21) Appl. No.: 16/105,334

(22) Filed: Aug. 20, 2018

(51) Int. Cl. H01L 21/67

(52) U.S. Cl. CPC H01L 21/67069

(57) ABSTRACT

A gas etching device includes an upper cover having a first gas exhausting channel that surrounds a first accommodation space. A lower cover has a second accommodation space where a wafer is located. The lower cover can connect with the upper cover. A gas jetting element is arranged in the first accommodation space to communicate with the upper cover. The gas jetting element receives etching gas from outside the upper cover and jets the etching gas in the first accommodation space and the second accommodation space to react with the wafer. The reacted etching gas is exhausted through the first gas exhausting channel. The first gas entering channel continues receives high-pressure gas from outside the upper cover and transmits the high-pressure gas to the second gas entering channel, so as to avoid leaking the etching gas.

### BACKGROUND OF THE INVENTION

### Field of the Invention

The present invention relates to a gas etching device, particularly to an etching device that uses gas to uniformly etch a wafer and avoids leaking poison gas.

### Description of the Related Art

In a semiconductor fabrication process, there are various techniques for processing wafers. One of the techniques is an etching method, which is used to etch a certain region of an etched object during dry and wet physical reactions or a chemical reaction. After the lithography process, the pattern of a mask is copied to a photoresist layer, such that the unnecessary regions of the photoresist layer are etched and the etched object is subsequently processed. Nowadays, the common etching methods include a dry etching method and a wet etching method, which respectively use liquid solutions or plasma.

The abovementioned etching methods have some drawbacks. For example, the wet etching method removes a film during a chemical reaction. When the components of an integrated circuit (IC) are scaled down, lateral etching phenomena will occur due to the fact that the chemical reaction of the wet etching method does not have directional properties, thereby forming undercut structures and distorting the line width of components. Thus, the wet etching method is not suited for small patterns. Although the dry etching method has better directional properties, the selectivity of the dry etching method is worse than that of the wet etching method, whereby the etched object is easily damaged.

To overcome the abovementioned problems, the applicant deeply studies the present etching process and equipment using the same and applies Taiwan patent No. M441927, which provides a vapor etching apparatus with multiple chambers and a multi-chamber apparatus for etching a wafer. In addition, the applicant of the present invention invents an novel etching device according to the flowing direction of etching gas, so as to solve the afore-mentioned problems of the prior art.

### SUMMARY OF THE INVENTION

A primary objective of the present invention is to provide a gas etching device, which uses ringing channels to control the flowing direction of gas. The inner channels are used to exhaust the etched gas and the outer channels receive high-pressure gas to avoid leaking poison gas and protect an environment outside the device.

Another objective of the present invention is to provide a gas etching device, which uses gas to etch a wafer in the device, provides a novel etching method different from dry and wet etching methods, and improves the efficiency for etching the wafer according to the flowing direction and uniformly-diffused properties of the gas.

To achieve the abovementioned objectives, the present invention provides a gas etching device, which comprises an upper cover having a first accommodation space, a first gas exhausting channel, and a first gas entering channel, the gas exhausting channel surrounds the first accommodation space, and the first gas entering channel surrounds the first gas exhausting channel; a lower cover arranged under the upper cover, the lower cover has a second accommodation space, a second gas exhausting channel, and a second gas entering channel, a wafer is arranged in the second accommodation space, the lower cover selectively moves to connect with the upper cover, and then the first accommodation space, the first gas exhausting channel, and the first gas entering channel respectively connect and communicate with the second accommodation space, the second gas exhausting channel, and the second gas entering channel; and a gas jetting element arranged in the first accommodation space of the upper cover, the gas jetting element communicates with the upper cover, after the upper cover connects with the lower cover, the gas jetting element receives etching gas from outside the upper cover and jets the etching gas in the first accommodation space and the second accommodation space to react with the wafer, the reacted etching gas is exhausted through the first gas exhausting channel and the second gas exhausting channel from the first accommodation space and the second accommodation space, and the first gas entering channel continues receiving high-pressure gas from outside the upper cover and transmitting the high-pressure gas to the second gas entering channel, so as to avoid leaking the etching gas to outside the upper cover and the lower cover

In an embodiment of the present invention, the perimeter of each of the upper cover and the lower cover is embedded with at least one heating element, and the at least one heating element maintains a temperature that the etching gas reacts with the wafer when the upper cover connects with the lower cover. The at least one heating element is a tubular heat exchanger.

In an embodiment of the present invention, the bottom of the second accommodation space of the lower cover further comprises at least three supporting columns, and the wafer is arranged on the at least three supporting columns.

In an embodiment of the present invention, the bottom of the second accommodation space of the lower cover further comprises a plurality of gas exhausting grooves that communicate with the second accommodation space and the second gas exhausting channel, and the reacted the etching gas is exhausted to outside the upper cover and lower cover through the plurality of gas exhausting grooves.

In an embodiment of the present invention, the lower cover is moved by an elevating device.

In an embodiment of the present invention, the gas etching device further comprises a gas exhausting assembly connected with the first gas exhausting channel of the upper cover through tubes, and the gas exhausting assembly exhausts the etching gas within the first accommodation space and the second accommodation space through the first gas exhausting channel and the second gas exhausting channel.

In an embodiment of the present invention, each of a joint between the first gas exhausting channel and the second gas exhausting channel and a joint between the first gas entering channel and the second gas entering channel is provided with a leak-proof element that avoids leaking the etching gas after the first gas exhausting channel and the first gas entering channel respectively connect and communicate with the second gas exhausting channel and the second gas entering channel.

In an embodiment of the present invention, the upper cover further comprises a gas entering hole formed on a bottom of the first accommodation space to connect with the gas jetting element, and the gas entering hole receives the etching gas from outside the upper cover and transmits the etching gas to the gas jetting element.

Below, the embodiments are described in detail in cooperation with the drawings to make easily understood the technical contents, characteristics and accomplishments of the present invention.

### BRIEF DESCRIPTION OF THE DRAWINGS

FIG. 1 is a diagram schematically showing an upper cover and a lower cover separating from each other according to an embodiment of the present invention;

FIG. 2 is a perspective view of an upper cover according to an embodiment of the present invention;

FIG. 3 is a perspective view of a lower cover according to an embodiment of the present invention;

FIG. 4 is a diagram schematically showing an upper cover with heating elements according to an embodiment of the present invention;

FIG. 5 is a diagram schematically showing a lower cover with heating elements according to an embodiment of the present invention; and

FIG. 6 is a diagram schematically showing an upper cover and a lower cover connected with each other according to an embodiment of the present invention.

### DETAILED DESCRIPTION OF THE INVENTION

In the present invention, chemical liquid is converted into chemical gas, such as vapor or fog. The chemical gas flows to encompass and etch an etched wafer, such that the gas etching technology different from dry and wet etching methods is provided. The gas etching device of the present invention can avoid leaking poison gas when gas etches the wafer.

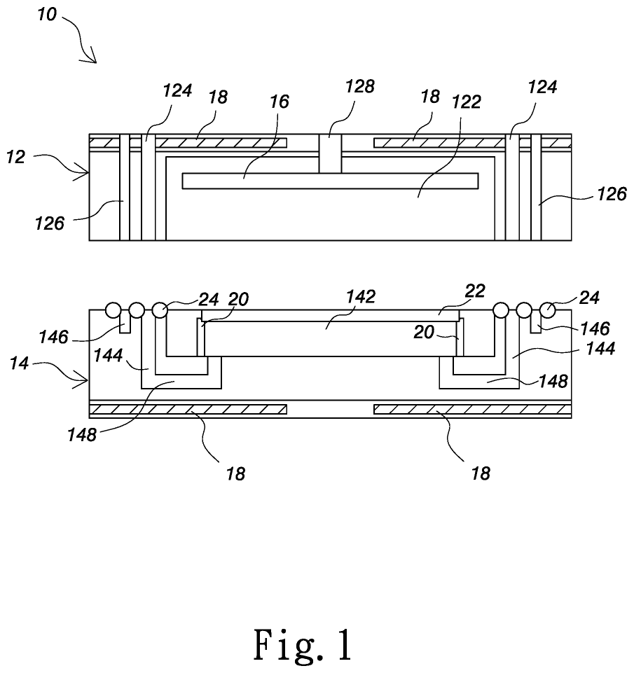

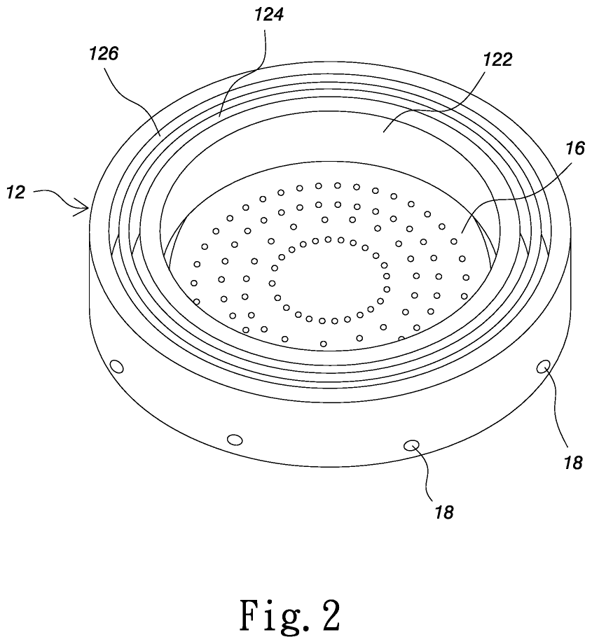

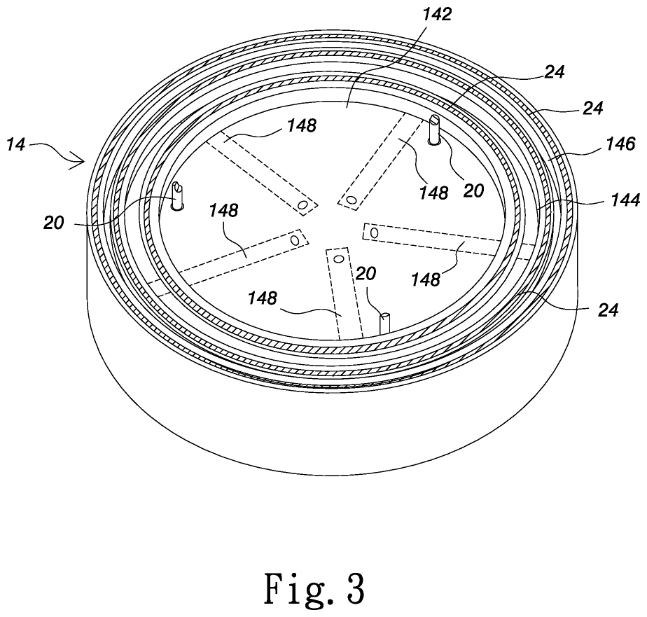

Refer to FIG. 1, FIG. 2, and FIG. 3. A gas etching device 10 comprises an upper cover 12, a lower cover 14, and a gas jetting element 16. The upper cover 12 has a first accommodation space 122, a first gas exhausting channel 124, and a first gas entering channel 126, and a gas entering hole 128. The gas exhausting channel 124 surrounds the first accommodation space 122. The first gas entering channel 126 surrounds the first gas exhausting channel 124. The gas jetting element is arranged on the bottom of the first accommodation space 122. The lower cover 14 is arranged under the upper cover 12. The lower cover 14 has a second accommodation space 142, a second gas exhausting channel 144, and a second gas entering channel 146. The second gas exhausting channel 144 surrounds the second accommodation space 142. The second gas entering channel 146 surrounds the second gas exhausting channel 144. The bottom of the second accommodation space 142 has a plurality of gas exhausting grooves 148 that communicate with the second accommodation space 142 and the second gas exhausting channel 144. The gas jetting element 16 is arranged in the first accommodation space 122 of the upper cover 12 to communicate with the gas entering hole 128 of the upper cover 12.

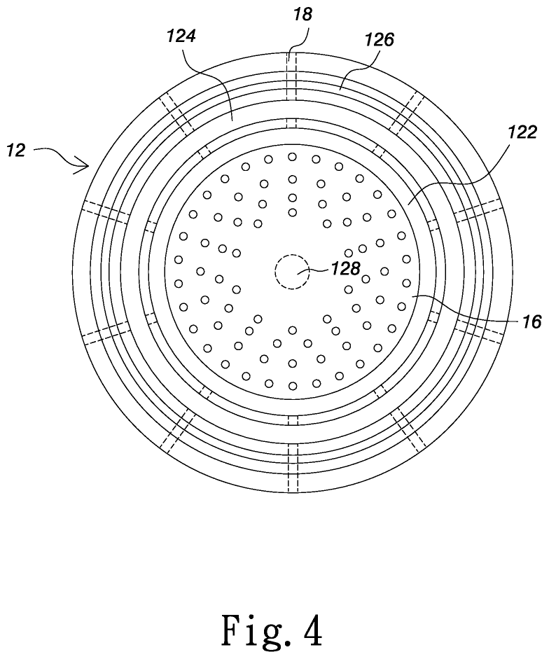

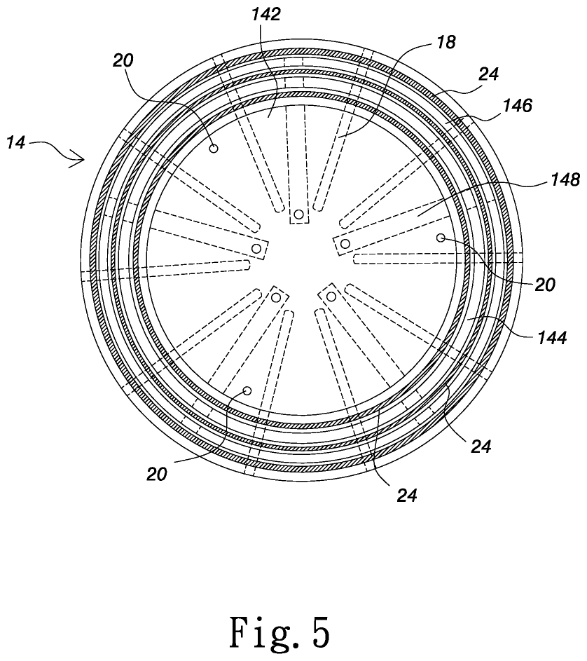

Refer to FIG. 4 and FIG. 5. Continuing from the abovementioned paragraph, the perimeter of each of the upper cover 12 and the lower cover 14 is embedded with at least one heating element 18, such as a tubular heat exchanger. For example, the bottoms of the upper cover 12 and the lower cover 14 are embedded with the heating elements 18. The bottom of each of the upper cover 12 and the lower cover 14 is embedded with ten heating elements 18. The scope of the present invention should not be limited to the type and number of the heating elements 18. In addition, the bottom of the second accommodation space 142 of the lower cover 14 may be provided with at least three supporting columns 20. In the embodiment, there are three supporting columns 20 for explanation.

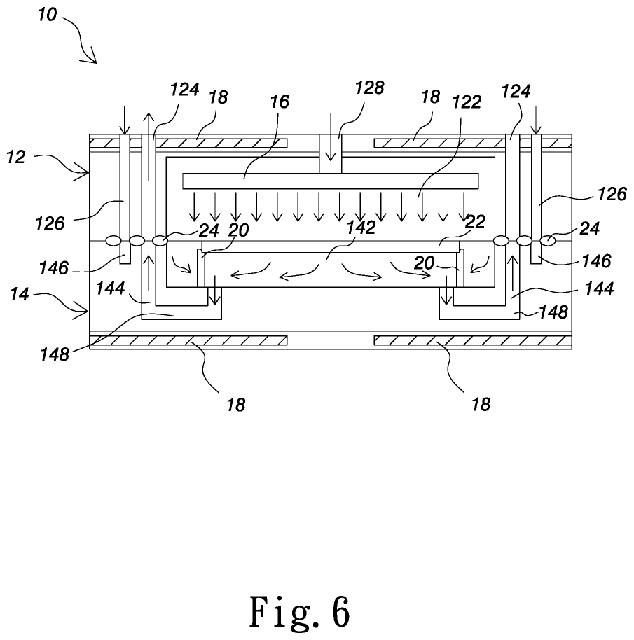

After describing the structure of the present invention, the operation of the present invention is described in detail. Refer to FIG. 6 and FIG. 1. The gas etching device 10 is like a chamber for etching of a semiconductor device. The scope of the present invention should not be limited to how to move a wafer 22 into the gas etching device 10. When the wafer 22 is moved into the gas etching device 10, the wafer 22 is located in the second accommodation space 142 of the lower cover 14. For example, the wafer 22 is supported by three supporting columns 20. After the wafer 22 is located on the supporting columns 20, the lower cover 14 may selectively move to connect with the upper cover 12. In an embodiment, the lower cover 14 may rise or fall by an elevating device (not shown) whereby the lower cover 14 connects with the upper cover 12. The elevating device may a pneumatic cylinder or a hydraulic cylinder, but the present invention is not limited thereto. In addition, each of a joint between the first gas exhausting channel 126 and the second gas exhausting channel 144 and a joint between the first gas entering channel 126 and the second gas entering channel 146 is provided with a leak-proof element 24, such as an O ring. The leak-proof element 24 is used as a buffer and prevents each of the joint between the first gas exhausting channel 126 and the second gas exhausting channel 144 and the joint between the first gas entering channel 126 and the second gas entering channel 146 from leaking gas due to cracks caused by tolerance in size when the upper cover 12 connects with the lower cover 14.

After the upper cover 12 connects with the lower cover 14, the first accommodation space 122 connects and communicates with the second accommodation space 142, the first gas exhausting channel 124 and the first gas entering channel 126 respectively connect and communicate with the second gas exhausting channel 144 and the second gas entering channel 146, whereby the wafer 22 is located in the first accommodation space 122 and the second accommodation space 142. The gas jetting element 16 receives etching gas from the gas entering hole 128 of the upper cover 12. That is to say, the etching gas is received from outside the upper cover 12 and transmitted to the gas jetting element 16 to jet. The present invention does not limit the type of the etching gas and the external pipe of the upper cover 12. The gas etching uniformly diffuses to fill the first accommodation space 122 and the second accommodation space 142 when the gas jetting element 16 jets the etching gas. The heating elements 18 are embedded in the perimeter of each of the upper cover 12 and the lower cover 14 maintain the temperature of the first accommodation space 122 and the second accommodation space 142 and the temperature of the etching gas to avoid liquefying the etching gas. The etching gas reacts with the wafer 22 on the supporting columns.

After the etching reaction, the etching gas is exhausted from the first accommodation space 122 and the second accommodation space 142 through the second gas exhausting channel 144 and the first gas exhausting channel 124. The present invention uses a gas exhausting assembly (not shown) such as a pump to connect with the first gas exhausting channel 124 of the upper cover 12 through a pipe. The gas exhausting assembly is used to exhaust the etching gas from the first accommodation space 122 and the second accommodation space 142 through the gas exhausting grooves 148, the second gas exhausting channel 144 and the first gas exhausting channel 124 to outside the gas etching device 10. Simultaneously, when the etching reaction is performed on the wafer 22 in the first accommodation space 122 and the second accommodation space 142 or when the gas exhausting assembly exhausts the reacted etching gas, the first gas entering channel 126 endlessly receives high-pressure gas such as clean dry air (CDA) from outside the upper cover 12 and transmits the high-pressure gas to the second high-pressure gas 146, so as to avoid leaking the etching gas that is reacting or leaking the reacted etching gas to outside the upper cover 12 and the lower cover 14.

In the chamber of the present invention, the etching gas is jetted to uniformly fill the accommodation space and react with the wafer and detectors for poison gas or gas pressure are installed. When leaking poison gas, the outer high-pressure gas prevents from leaking to outside the chamber to protect staffs working around the chamber. The present invention separates the upper cover from the lower cover to conveniently pass the wafer in and out. As long as a robotic arm is installed outside the gas etching device, the robotic arm can easily pass the wafer in and out. The scope of the present invention is not limited to the equipment outside the gas etching device.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A gas etching device comprising:
an upper cover having a first accommodation space, a first gas exhausting channel, and a first gas entering channel, the gas exhausting channel surrounds the first accommodation space, and the first gas entering channel surrounds the first gas exhausting channel;
a lower cover arranged under the upper cover, the lower cover has a second accommodation space, a second gas exhausting channel, and a second gas entering channel, a wafer is arranged in the second accommodation space, the lower cover selectively moves to connect with the upper cover, and then the first accommodation space, the first gas exhausting channel, and the first gas entering channel respectively connect and communicate with the second accommodation space, the second gas exhausting channel, and the second gas entering channel; and
a gas jetting element arranged in the first accommodation space of the upper cover, the gas jetting element communicates with the upper cover, after the upper cover connects with the lower cover, the gas jetting element receives etching gas from outside the upper cover and jets the etching gas in the first accommodation space and the second accommodation space to react with the wafer, reacted the etching gas is exhausted through the first gas exhausting channel and the second gas exhausting channel from the first accommodation space and the second accommodation space, and the first gas entering channel continues receiving high-pressure gas from outside the upper cover and transmitting the high-pressure gas to the second gas entering channel, so as to avoid leaking the etching gas to outside the upper cover and the lower cover.

2. The gas etching device according to claim 1, wherein a perimeter of each of the upper cover and the lower cover is embedded with at least one heating element, and the at least one heating element maintains a temperature that the etching gas reacts with the wafer when the upper cover connects with the lower cover.

3. The gas etching device according to claim 2, wherein the at least one heating element is a tubular heat exchanger.

4. The gas etching device according to claim 1, wherein a bottom of the second accommodation space of the lower cover further comprises at least three supporting columns, and the wafer is arranged on the at least three supporting columns.

5. The gas etching device according to claim 4, wherein the bottom of the second accommodation space of the lower cover further comprises a plurality of gas exhausting grooves that communicate with the second accommodation space and the second gas exhausting channel, and the reacted the etching gas is exhausted to outside the upper cover and lower cover through the plurality of gas exhausting grooves.

6. The gas etching device according to claim 1, wherein the lower cover is moved by an elevating device.

7. The gas etching device according to claim 1, further comprising a gas exhausting assembly connected with the first gas exhausting channel of the upper cover through tubes, and the gas exhausting assembly exhausts the etching gas within the first accommodation space and the second accommodation space through the first gas exhausting channel and the second gas exhausting channel.

8. The gas etching device according to claim 7, wherein the gas exhausting assembly is a pump.

9. The gas etching device according to claim 1, wherein the high-pressure gas is clean dry air (CDA).

10. The gas etching device according to claim 1, wherein each of a joint between the first gas exhausting channel and the second gas exhausting channel and a joint between the first gas entering channel and the second gas entering channel is provided with a leak-proof element that avoids leaking the etching gas after the first gas exhausting channel and the first gas entering channel respectively connect and communicate with the second gas exhausting channel and the second gas entering channel.

11. The gas etching device according to claim 10, wherein the leak-proof element is an O ring.

12. The gas etching device according to claim 1, wherein the upper cover further comprises a gas entering hole formed on a bottom of the first accommodation space to connect with the gas jetting element, and the gas entering hole receives the etching gas from outside the upper cover and transmits the etching gas to the gas jetting element.
